(19) United States
(12) Patent Application Publication
(10) Pub. No.: US 2007/0063253 A1
(43) Pub. Date: Mar. 22, 2007

(54) Semiconductor device and method of manufacturing the same

(76) Inventor: Kang Sik Choi, Kyoungki-do (KR)

Correspondence Address: LADAS & PARRY LLP, 224 SOUTH MICHIGAN AVENUE, SUITE 1600, CHICAGO, IL, 60604, US

(21) Appl. No.: 11/267,236

(22) Filed: Nov. 4, 2005

(30) Foreign Application Priority Data
Sep. 16, 2005 (KR) 10-2005-0086733

(51) Int. Cl. H01L 29/788; H01L 21/8242; H01L 21/336

(52) U.S. Cl. 257/315; 438/300; 438/243

(57) ABSTRACT

A semiconductor device and a method of manufacturing the same can satisfy a design rule reduction in a peripheral region. The semiconductor device includes a silicon substrate having an activation region formed by recessing a center portion of the silicon substrate lengthwise. A device isolation layer is formed on the silicon substrate for restricting the activation region. A gate is formed on the recessed activation region and has a smaller length than that of the recess, a source/drain extension region formed on a surface of the recessed activation region having no gate, spacers formed on both sidewalls of the gate, and a source/drain region formed on a surface of the activation region including the spacers at both sides of the gate.

### BACKGROUND OF THE INVENTION

1. Field of the invention

The present invention relates to a semiconductor device, and more particularly to a semiconductor device and a method of manufacturing the same, which can satisfy a design rule reduction in a peripheral region.

2. Description of the Prior Art

A channel length of a transistor formed in a cell region is reduced as a design rule of the semiconductor device is reduced. As a result, a structure of an existing planar transistor cannot establish a target threshold voltage Vₜ required by certain device in view of device structure and processes. Thus, research for a transistor having a recess gate structure has been widely developed in which gates are formed in grooves to increase channel length after the grooves are formed by etching a part of a silicon substrate on which the gates are formed.

Meanwhile, the design rule reduction is applied not only to a pattern formed in cell regions but also to a pattern formed in peripheral regions. Further, it is necessarily required to secure a margin in a single channel even when the transistor is formed in the peripheral region.

Therefore, various methods for lateral shrink and vertical shrink have been proposed. For example, a thickness reduction of a gate oxide layer, a formation of a source/drain extension region (referred to as SDE region) and a depth reduction of the SDE region have been proposed for the vertical shrink.

With relation to the method, however, the depth reduction of the SDE region cannot be substantially realized in view of a predetermined amount of silicon consumed in a subsequent silicide process. Therefore, an elevated source/drain structure for extending a source/drain region, which is formed through an epitaxial process after etching a gate spacer, has been proposed in order to account for this deficiency.

However, in order to apply the elevated source/drain structure, it is necessary to employ a new process, so called “Epitaxy”, which requires an investment in new equipment.

In addition, there is a problem in that a device characteristic deteriorates due to a high temperature epitaxial process. Furthermore, there is another problem in that the application of the elevated source/drain structure allows a change of a characteristic of a transistor according to uniformity and shape of epitaxial growth (See Low Thermal Budget Elevated Source/Drain Technology Utilizing Novel Solid Phase Epitaxy and Selective Vapor Phase Etching, 2000 IEDM, on page 433).

Thus, it is substantially difficult to apply the elevated source/drain structure to the peripheral region. Therefore, it is necessary to rapidly apply a new structure or method which satisfies the design rule reduction in the peripheral region without a complicated process resulting from the new structure or method.

### SUMMARY OF THE INVENTION

Accordingly, the present invention has been developed in order to solve the above-mentioned problems occurring in the prior art, and an object of the present invention is to provide a semiconductor device and a method of manufacturing the same, which can satisfy a design rule reduction in a peripheral region without a complicated process.

Another object of the present invention is to provide a semiconductor device and a method of manufacturing the same, which can meet a design rule reduction in a peripheral region with an accomplishment of a stable process.

Still another object of the present invention is to provide a semiconductor device and a method of manufacturing the same, which can meet a design rule reduction in a peripheral region with an accomplishment of a stable characteristic of the semiconductor device.

According to an aspect of the present invention to accomplish these objects, there is provided a semiconductor device including: a silicon substrate including an activation region formed by recessing a center portion of the silicon substrate lengthwise; a device isolation layer formed on the silicon substrate for restricting the activation region; a gate formed on the recessed activation region and having smaller than a length of a recess; a source/drain extension region formed on a surface of the recessed activation region having no gate; spacers formed on both sidewalls of the gate; and a source/drain region formed on a surface of the activation region including the spacers at both sides of the gate.

Here, the recess has a depth which is about one third to one half of the depth of the source/drain region. The recess has a length in which the width of the recessed activation region having gate is 1.5˜2 times the width of the spacers.

The spacers are formed only on the recessed activation region.

According to another aspect of the present invention to accomplish these objects, there is provided a method of manufacturing a semiconductor device including the steps of: forming a device isolation layer to restrict an activation region on a silicon substrate; recessing a center portion of the activation region lengthwise; forming a gate on the recessed activation region by exposing both edges of the recessed activation region; forming a source/drain extension region at both sides of the gate on a surface of the recessed activation region; forming an insulation layer with enough thickness to completely bury the recessed activation region at both sides of the gate on a surface of the silicon substrate; forming spacers at both sidewalls of the gate by etching the insulation layer; and forming a source/drain region at both sides of the gate including the spacers on the activation region.

Here, the activation region is recessed at a depth less than that of the source/drain region, preferably at the depth of one third to one half the depth of the source/drain region at the recessing step. The activation region is recessed so that the recessed activation region having no gate has a width of 1.5˜2 times that of the spacers, at the recessing step.

The spacers are formed and arranged only on the recessed activation region. The spacers are formed by etching the insulation layer until a surface of the activation region of the silicon substrate is exposed while preventing the insulation buried in the recessed activation region at both sides of the gate.

### BRIEF DESCRIPTION OF THE DRAWINGS

The above and other objects, features, and advantages of the present invention will be more apparent from the following detailed description taken in conjunction with the accompanying drawings, in which:

FIGS. 1A to 1F are sectional views illustrating a method of manufacturing a semiconductor device according to the present invention, in which the semiconductor device is shown in sections step by step; and

FIGS. 2 to 4 are sectional views illustrating the relation between a size of a recessed activated region without a gate and a size of spacer which results from misalignment.

### DETAILED DESCRIPTION OF THE PREFERRED EMBODIMENTS

Hereinafter, a preferred embodiment of the present invention will be described with reference to the accompanying drawings.

According to a technical principle of the present invention, the present invention realizes a transistor having an elevated source/drain structure in a peripheral region by using a method of recessing an expected channel region, instead of using a method of growing a silicon layer on a source/drain region having a smaller depth by implementing an epitaxial process.

In this case, the present invention can obtain a single channel margin by realizing an elevated source/drain structure, thereby manufacturing a semiconductor device which can satisfy a design rule reduction in a peripheral region. Especially, since the present invention need not perform an existing epitaxial process to obtain the elevated source/drain structure, the present invention allows the quite simple process. Further, the present invention can manufacture the semiconductor device to meet the design rule reduction in the peripheral region with a stable process and characteristics of the semiconductor device.

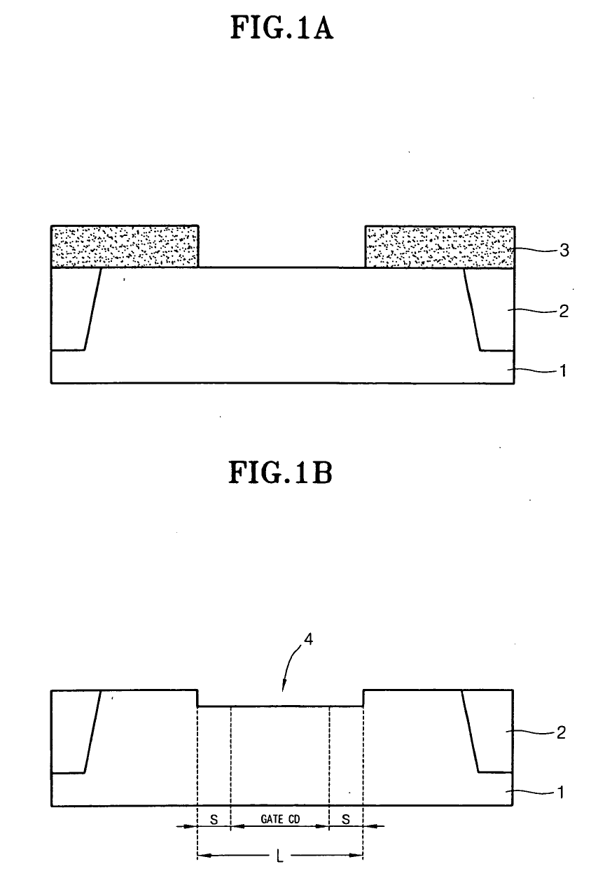

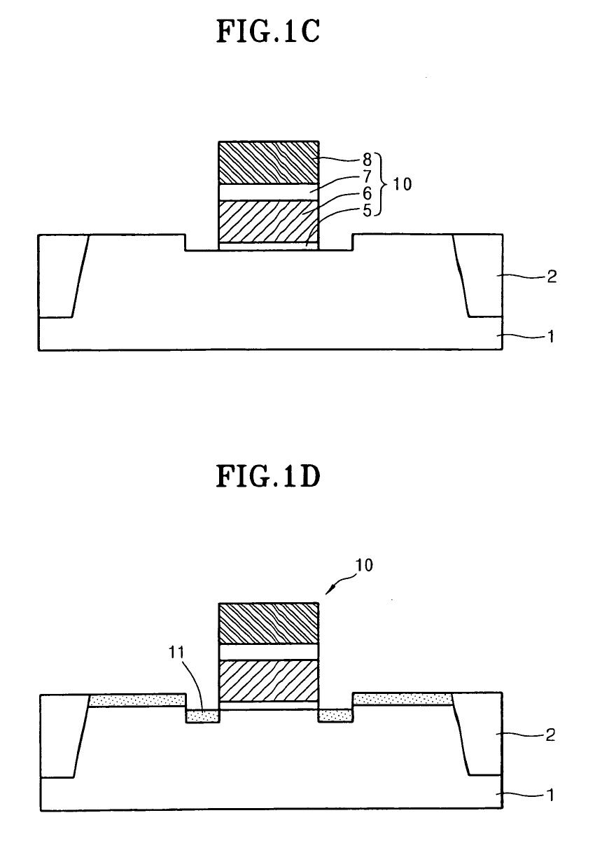

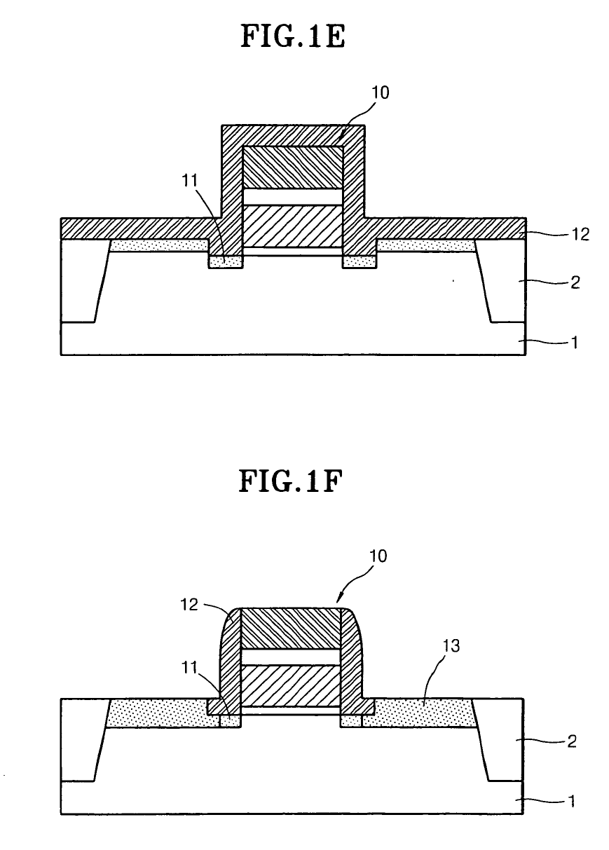

FIGS. 1A to 1F are sectional views illustrating a method of manufacturing a semiconductor device according to the method of the present invention. Hereinafter, the method of manufacturing the semiconductor device will be described through drawings and the description of these drawings related to the peripheral region.

Referring to FIG. 1A, a silicon substrate 1 is prepared on which a trench type device isolation layer 2 is formed to restrict an activation region in the peripheral region according to a known Shallow Trench Isolation process. Then, a photoresist layer is coated on the whole surface of the semiconductor substrate 1 having the device isolation layer 2. Thereafter, the coated photoresist layer is exposed to light and developed, so that a photoresist pattern 3 having an exposed central portion, i.e. an expected channel region, is formed.

Referring to FIG. 1B, the exposed activation region of the semiconductor device is etched to a predetermined depth by using the photoresist pattern as an etching mask, thereby recessing the activation region corresponding to the channel region. Then, the photoresist pattern used as the etching mask is removed by using an established process known as an O₂ ashing process.

Reference numeral 4 refers to the recessed activation region. The depth of the recessed activation region 4 generally is smaller than one half depth of the source/drain region to be formed after the formation of the recessed activation region, preferably in a range of about one third to one half of the depth of the source/drain region. The length of the recessed activation region 4, i.e. a length L of the recess is equal to a sum of a width CD of the gate and widths s between the gate and ends of the recessed activation region (L=gate CD+2*s).

The recess of the channel region in the peripheral region is preferably formed when a recess gate is etched in a cell region in a case of manufacturing DRAM device having a recess gate scheme in the cell region.

Referring to FIG. 1C, known ion implant processes including a well ion implant process and a threshold voltage ion implant process, are sequentially performed on the semiconductor substrate.

Gate insulation layer 5, gate conductive layers 6 and 7 and gate hardmask layer 8 are sequentially formed on the surface of the semiconductor substrate, which in turn are sequentially etched to form a gate 10 on the recessed activation region 4. At this time, the gate 10 is formed in order that both edges of the recessed activation region 4 are exposed.

Here, the gate insulation layer 5 includes an oxide layer, a nitride layer or stacked layers of the oxide layer and the nitride layer. The gate conductive layers 6 and 7 include a polysilicon layer 6 and a metal interlayer 7, i.e. a metal layer or a stacked layer of a metal silicide layer. The gate hardmask layer 8 includes a nitride layer.

Referring to FIG. 1D, an ion implant process is performed in the resultant semiconductor substrate by using the gate 10 as an ion-implant mask, so that the source/drain extension region 11 is formed at sides of the gate 10 in the activation region on a surface of the semiconductor substrate, more particularly in the recessed activation region having no gate 10 on a surface of the semiconductor substrate.

Referring to FIG. 1E, an insulation layer 12 including an oxide layer or a nitride layer is formed on the surface of the semiconductor substrate in order to cover the gate 10. The thickness of the insulation layer 12 is greater than one half of the width s of a space between gate 10 and the ends of the recessed activation region so as to cover the space between the gate 10 and the ends of the recessed activation region (referred to as the recess ends).

Referring to FIG. 1F, the insulation layer 12 is blanket-etched, thereby forming spacers 12a on both side walls of the gate 10. At this time, the spacers 12a are formed only on the recessed activation region 4, more particularly formed to be arranged only on the source/drain extension region 11 formed in the surface of the recessed activation region having no gate 10. In addition, the insulation layer 12 is etched until the non-recessed activation region on the surface of the semiconductor device is exposed, so as to form the spacers 12a in order not to etch the insulation layer which is buried in the recessed activation region having no the gate 10.

Then, a source/drain ion implantation process is performed in the resultant semiconductor substrate, so as to form the source/drain region 13 in the surface of the activation region around the gate 10 including the spacers 12a. At this time, since the space between the gate 10 and the recess ends remains to be buried by the spacers 12a, a change of a source/drain junction profile cannot be caused.

Although not shown, a series of known succeeding processes is sequentially carried out to complete the manufacture of the semiconductor device according to the present invention.

As described above, the channel region is preliminary recessed, so that it is possible to obtain the elevated source/drain structure without performing the epitaxial process. Thus, it is possible to obtain the source/drain region having the depth almost equal to that of the source/drain extension region, resulting in a significant improvement of the single channel margin. It is unnecessary to perform the epitaxial process, so that it can fundamentally prevent a defect in the epitaxial processes and a deterioration of the characteristic of the semiconductor device.

With the manufacture of the semiconductor according to the present invention, misalignment of the gate may happen in the processes of forming the gate. This has an adverse effect on the improvement of the single channel margin. As described above, however, the present invention can still obtain the single channel margin in spite of the misalignment of the gate by setting the depth of the insulation layer to be larger than one half of the width of the spaces between the gate and the recess end, in other words, by setting the width of the space to be about 2 times the width of the spacers, preferably, to be 1.5˜2 times the width of the spacers.

More particularly, in the process of recessing the activation region of the silicon substrate, the width of the space between the gate and the recess end is set to be larger than the error range of misalignment. Specially, the width of the space is set to be equal to or smaller than 2 times the width of the spacers.

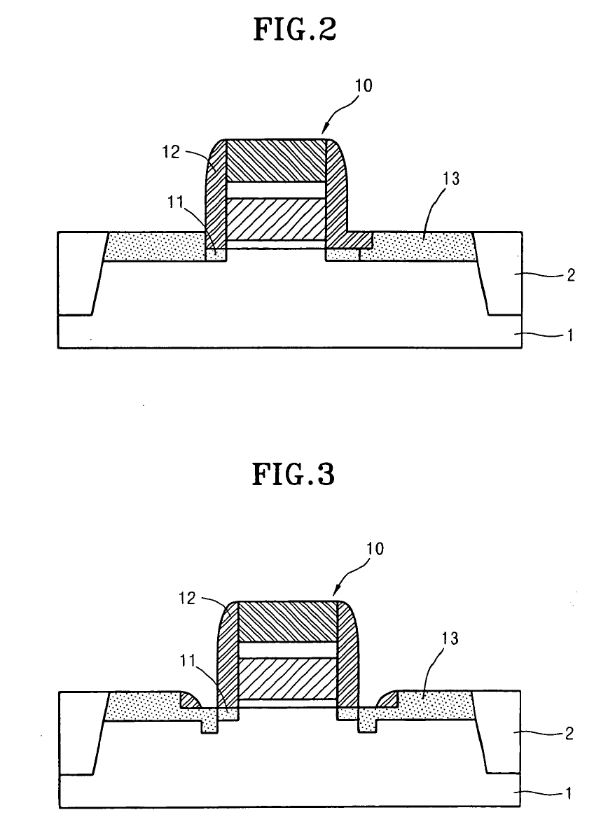

As shown in FIG. 2, it is possible to prevent a shape deformation of the source/drain region 13 if misalignment of the gate is present. Therefore, characteristic change of the transistor can be also prevented, resulting in a security of the single channel margin.

As shown in FIG. 3, in the case where the width s of the space between the gate 10 and the recess end is two times the width of the spacers 12a, the source/drain region 13 is formed so that it is deeper than the source/drain extension region 11. Thus, it is nearly impossible to improve the single channel margin.

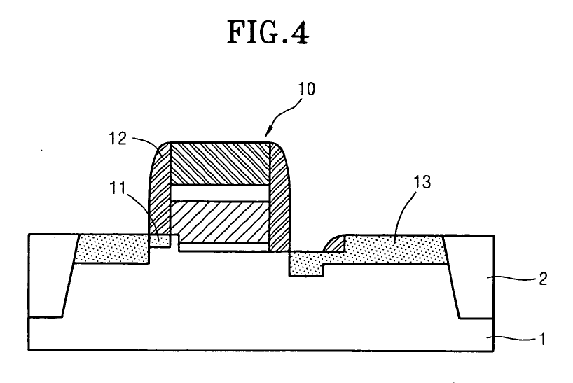

As shown in FIG. 4, in the case where the sum of all dimensions of the misalignment and the spacer 12a is larger than the width of the space between the gate 10 and the recess end, the gate 10 and the source/drain region 13 are deformed by a possible misalignment. This makes it difficult to achieve the single channel margin. Accordingly, the characteristic and the uniformity of the transistor are significantly decreased.

Therefore, with the semiconductor device of the present invention, the width of the space between the gate and the recess end is set to be larger than the error range of the misalignment while setting it to be equal to or smaller than two times the width of the spacer.

According to the present invention as described above, a channel region is recessed when a transistor is formed in a peripheral region, so that it is possible to achieve a transistor having an elevated source/drain structure without the epitaxial process. Accordingly, the present invention can promote a more stable process as well as a more stable characteristic to the device by excluding the epitaxial process. As a result, the present invention can manufacture the semiconductor device to meet the design rule reduction in the peripheral region by forming the elevated source/drain structure while making the process and the characteristic of the semiconductor device stable without the requirement of a complicated process.

While a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A semiconductor device comprising:
a silicon substrate including an activation region formed by recessing a center portion of the silicon substrate;
a device isolation layer formed on the silicon substrate for restricting the activation region;
a gate formed on the activation region and having a smaller length than that of the recess;
a source/drain extension region formed on a surface of the activation region having no gate;
spacers formed on both sidewalls of the gate; and
a source/drain region formed on a surface of the activation region including the spacers at both sides of the gate.

2. The semiconductor device as claimed in claim 1, wherein the recess has a depth, which is between about one-third to one-half of a depth of the source/drain region.

3. The semiconductor device as claimed in claim 1, wherein the recess has a length in which a width of the recessed activation region having no gate is 1.5˜2 times a width of the spacers.

4. The semiconductor device as claimed in claim 1, wherein the spacers are formed only on the recessed activation region.

5. A method of manufacturing a semiconductor device, comprising the steps of:
forming a device isolation layer to restrict an activation region on a silicon substrate;
recessing a center portion of the activation region lengthwise;
forming a gate on the recessed activation region by exposing both edges of the recessed activation region;
forming a source/drain extension region at both sides of the gate on a surface of the recessed activation region;
forming an insulation layer with enough thickness to completely bury the recessed activation region at both sides of the gate on a surface of the silicon substrate;
forming spacers at both sidewalls of the gate by etching the insulation layer; and
forming a source/drain region at both sides of the gate including the spacers on the activation region.

6. The method of manufacturing the semiconductor device as claimed in claim 5, wherein the activation region is recessed at a depth smaller than that of the source/drain region, preferably at the depth of one third to one half the depth of the source/drain region at the recessing step.

7. The method of manufacturing the semiconductor device as claimed in claim 5, wherein the activation region is recessed so that the recessed activation region having no gate has a width of 1.5˜2 times that of the spacers, at the recessing step.

8. The method of manufacturing the semiconductor device as claimed in claim 5, wherein the spacers are formed so as to be arranged only on the recessed activation region.

9. The method of manufacturing the semiconductor device as claimed in claim 5, wherein the spacers are formed by etching the insulation layer until the surface of the activation region of the silicon substrate is exposed while preventing the insulation layer, which is buried in the recessed activation region at both sides of the gate, from being etched.
